(19) United States
(12) Patent Application Publication
(10) Pub. No.: US 2013/0112237 A1
(43) Pub. Date: May 9, 2013

(54) PHOTOVOLTAIC-THERMAL SOLAR ENERGY COLLECTOR WITH INTEGRATED BALANCE OF SYSTEM

(71) Applicants: GILAD ALMOGY, Palo Alto, CA (US); Ratson Morad, Palo Alto, CA (US); Michael Jeffrey Starkey, Mountain View, CA (US); Andrew Burke Campbell, San Jose, CA (US)

(72) Inventors: GILAD ALMOGY, Palo Alto, CA (US); Ratson Morad, Palo Alto, CA (US); Michael Jeffrey Starkey, Mountain View, CA (US); Andrew Burke Campbell, San Jose, CA (US)

(73) Assignee: COGENRA SOLAR, INC., MOUNTAIN VIEW, CA (US)

(21) Appl. No.: 13/291,531

(22) Filed: Nov. 8, 2011

(51) Int. Cl. H01L 31/058; F25B 27/00; F24J 2/38; H01L 31/052; F24J 2/04

(52) U.S. Cl. 136/246; 136/248; 126/646; 126/600; 62/235.1; 62/238.7

(57) ABSTRACT

Systems, methods, and apparatus by which solar energy may be collected to provide electricity, heat, or a combination of electricity and heat are disclosed herein.

### FIELD OF THE INVENTION

The invention relates generally to the collection of solar energy to provide electric power, heat, or electric power and heat.

### BACKGROUND

Alternate sources of energy are needed to satisfy ever increasing world-wide energy demands. Solar energy resources are sufficient in many geographical regions to satisfy such demands, in part, by provision of electric power and useful heat.

### SUMMARY

Systems, methods, and apparatus by which solar energy may be collected to provide electricity, heat, or a combination of electricity and heat are disclosed herein.

In one aspect, an integrated balance of system for a photovoltaic-thermal solar energy collector comprises an inverter configured to convert direct current received from the solar energy collector to alternating current, and a heat transfer fluid control system configured to circulate a heat transfer fluid through the solar energy collector. The heat transfer control system includes a controller, a pump controlled by the controller, and a power supply electrically coupled to the inverter to receive alternating current electric power from the inverter. The power supply provides electric power to the controller and to the pump.

The integrated balance of system may further comprise an alternating current electric power outlet electrically coupled to the inverter to provide alternating current from the inverter to an external load, a first heat transfer fluid inlet configured to receive heat transfer fluid from an external supply, a first heat transfer fluid outlet configured to provide heat transfer fluid received from the external supply to the solar energy collector, a second heat transfer fluid inlet configured to receive heat transfer fluid from the solar energy collector, and a second heat transfer fluid outlet configured to provide heat transfer fluid received from the solar energy collector to an external use or external user.

The integrated balance of system may be configured, in some variations, as one or more prefabricated portable modules shippable to a site of the solar energy collector for integration with the solar energy collector. In such variations, the one or more modules may together have, for example, a width of about 1.0 meters to about 1.6 meters and a depth of about 0.3 meters to about 0.5 meters. The total footprint of the integrated balance of system may be, for example less than about 1.0 square meters, less than about 0.8 square meters, less than about 0.5 square meters, less than about 0.3 square meters, or less than about 0.25 square meters.

In any of the above variations, the electrical and fluid inputs and outputs from the integrated balance of system may use standard connections that reduce the expertise required to connect the integrated balance of system to the solar energy collector, to an external use or external user of heat generated by the solar energy collector, and/or to an external electric load, such as an external electric grid, served by the solar energy collector. This may make installation of the integrated balance of system relatively fast, easy, and inexpensive. The alternating current electric power outlet may satisfy, for example, the American National Standards Institute National Electrical Code NFPA 70 (edition effective Aug. 25, 2010) or its equivalent in other national or regional jurisdictions. The heat transfer fluid inlets and outlets (e.g., fittings) may satisfy, for example, the American National Standards Institute National Tapered Pipe Thread standard B1.20.1 (edition effective Aug. 31, 1983, reaffirmed in 2001), or its equivalent in other national or regional jurisdictions.

In any of the above variations, the power supply in the integrated balance of system may be configured to switch from operating on alternating current provided by the inverter to operating on direct current provided by local electric power storage if alternating current electric power from the inverter becomes unavailable. Alternatively, the power supply may be configured to switch from operating on alternating current provided by the inverter to operating on direct current generated by the solar energy collector if alternating current electric power from the inverter becomes unavailable. The power supply may also be configured to switch from operating on alternating current provided to the inverter to operating on both direct current provided by local electric power storage and direct current generated by the solar energy collector in the event that alternating current from the inverter is not available.

In any of the above variations, the power supply may be configured to provide electric power to the solar energy collector to power a tracker that adjusts an orientation of the solar energy collector to track the sun as it moves across the sky.

In any of the above variations, the controller may be coupled to the inverter to receive signals from the inverter comprising information about the operation of the inverter.

In any of the above variations, the pump may be a variable speed pump with speed controlled by the controller depending on a temperature of the heat transfer fluid. The temperature of the heat transfer fluid may be measured, for example, after the heat transfer fluid has been heated in the solar energy collector and prior to the heat transfer fluid being supplied to the external use or external user. Making the temperature measurement in this manner may avoid any need to measure or otherwise know the temperature of the heat transfer fluid at the external use or external user, or at a tank or other reservoir at or near the external use or external user.

Any of the above variations of the integrated balance of system may comprise a wireless communicator (for example, a radio) coupled to the controller to receive signals from the controller and configured to communicate wirelessly with another substantially similar integrated balance of system.

Any of the above variations of the integrated balance of system may comprise a wireless communicator (for example, a radio) coupled to the controller to receive signals from the controller and configured to communicate wirelessly with a computer. The computer may be connected, for example, to a computer network such as, for example, the Internet.

In another aspect, a solar energy collector system comprises at least a first solar energy collector and at least a first integrated balance of system located proximate the first solar energy collector. The solar energy collector includes a solar energy receiver, a reflector, and a tracker configured to orient the reflector, the receiver, or the reflector and the receiver to track motion of the sun in the sky so that solar radiation is concentrated by the reflector onto the receiver. The receiver includes one or more solar cells that, in operation of the solar energy collector, are illuminated by solar radiation concentrated by the reflector onto the receiver. The receiver also includes one or more fluid channels through which, in operation of the solar energy collector, heat transfer fluid may pass to collect heat from solar radiation concentrated by the reflector onto the receiver.

The integrated balance of system includes an inverter electrically coupled to the receiver to receive direct current from the solar energy collector and configured to convert the direct current to alternating current, and a heat transfer fluid control system configured to circulate a heat transfer fluid through the solar energy collector. The heat transfer control system includes a controller, a pump controlled by the controller, and a power supply electrically coupled to the inverter to receive alternating current electric power from the inverter. The power supply provides electric power to the controller and to the pump.

The integrated balance of system may further comprise an alternating current electric power outlet electrically coupled to the inverter to provide alternating current from the inverter to an external load, a first heat transfer fluid inlet configured to receive heat transfer fluid from an external supply, a first heat transfer fluid outlet coupled to the receiver to provide heat transfer fluid received from the external supply to the solar energy collector, a second heat transfer fluid inlet coupled to the receiver to receive heat transfer fluid from the solar energy collector, and a second heat transfer fluid outlet configured to provide heat transfer fluid received from the solar energy collector to an external use or external user.

Any of the variations of the integrated balance of system described above with respect to the first aspect may be used in the solar energy collector system of the second aspect.

Any of the above variations of the solar energy collector system may comprise local heat transfer fluid storage fluidly coupled to the integrated balance of system to receive and store heat transfer fluid that has been heated in the solar energy collector.

Any of the above variations of the solar energy collector system may comprise a local heat transfer fluid cooler fluidly coupled to the integrated balance of system and configured to receive heat transfer fluid from the external supply. The heat transfer fluid cooler may be used to cool heat transfer fluid received from the external supply to below a desired temperature before the heat transfer fluid circulates through the solar energy collector. The cooler may be, for example, an air-cooled radiator or other form of dry heat exchanger. Active chillers or any other suitable cooling system may also be used. The controller in the integrated balance of system may, for example, control one or more valves to route heat transfer fluid from the external supply through the heat transfer fluid cooler prior to circulating the heat transfer fluid through the solar energy collector or, alternatively, control the valves to bypass the heat transfer fluid cooler.

In any of the above variations, the power supply may provide electric power to the solar energy collector to power the tracker. In some such variations, the receiver includes solar cells that generate sufficient direct current electric power under a solar irradiance of about 20, about 25, about 28, about 30, about 35, about 40, or about 45 Watts per square meter of solar cell to power the tracker.

Any of the above variations of the solar energy collector system may comprise a second solar energy collector located proximate the first solar energy collector and a second integrated balance of system located proximate to the second solar energy collector. The second solar energy collector may include a solar energy receiver, a reflector, and a tracker configured to orient the reflector, the receiver, or the reflector and the receiver to track motion of the sun in the sky so that solar radiation is concentrated by the reflector onto the receiver. The receiver may include one or more solar cells that, in operation of the solar energy collector, are illuminated by solar radiation concentrated by the reflector onto the receiver. The receiver may also include one or more fluid channels through which, in operation of the solar energy collector, heat transfer fluid may pass to collect heat from solar radiation concentrated by the reflector onto the receiver.

The second integrated balance of system may include an inverter electrically coupled to the receiver in the second solar energy collector to receive direct current from the second solar energy collector and configured to convert the direct current to alternating current, and a heat transfer fluid control system configured to circulate a heat transfer fluid through the second solar energy collector. The heat transfer control system may include a controller, a pump controlled by the controller, and a power supply electrically coupled to the inverter to receive alternating current electric power from the inverter. The power supply may provide electric power to the controller and to the pump.

The second integrated balance of system may further comprise an alternating current electric power outlet electrically coupled to the inverter to provide alternating current from the inverter to an external load the same as or different from the external load to which the first integrated balance of system is coupled, a first heat transfer fluid inlet configured to receive heat transfer fluid from an external supply the same as or different from the external supply to which the first integrated balance of system is coupled, a first heat transfer fluid outlet coupled to the receiver in the second solar energy collector to provide heat transfer fluid received from the external supply to the second solar energy collector, a second heat transfer fluid inlet coupled to the receiver in the second solar energy collector to receive heat transfer fluid from the second solar energy collector, and a second heat transfer fluid outlet configured to provide heat transfer fluid received from the second solar energy collector to an external use or external user the same as or different from that of the first integrated balance of system.

In such variations including first and second solar energy collectors and first and second integrated balance of system, the first integrated balance of system controls the direct current electric output of the first solar energy collector at a first current-voltage power point and controls the temperature and flow rate of heat transfer fluid through the first solar energy collector at a first output temperature and a first flow rate. The second integrated balance of system controls the direct current electric output of the second solar energy collector at a second current-voltage power point and controls the temperature and flow rate of heat transfer fluid through the second solar energy collector at a second output temperature and a second flow rate. The first current voltage power point, first output temperature, and first flow rate may be controlled independently of the second current-voltage power point, second output temperature, and second flow rate.

In any of the above variations of the solar energy collector system in which the power supply may power the tracker, a method of operating the solar energy collector may comprise detecting a fault on the external load, ceasing to provide alternating current from the inverter to the external load, and powering the tracker from the power supply to orient the reflector, the receiver, or the reflector and the receiver to reduce or stop concentrating solar radiation onto the receiver. The method may comprise the power supply powering the tracker with stored electric power. Alternatively, or in addition, the method may comprise the power supply powering the tracker with direct current electric power generated by the solar energy collector.

As an alternative to the method just described, in any of the above variations of the solar energy collector system in which the power supply may power the tracker, a method of operating the solar energy collector may comprise detecting a fault on the external load, ceasing to provide alternating current from the inverter to the external load, powering the pump to continue circulating heat transfer fluid through the solar energy collector, and powering the tracker from the power supply to continue orienting the receiver, the reflector, or the receiver and the reflector to concentrate solar radiation onto the receiver and thereby produce heated heat transfer fluid for the external use or external user. The method may comprise the power supply powering the tracker and the pump with stored electric power. Alternatively, or in addition, the method may comprise the power supply powering the tracker and the pump with direct current electric power generated by the solar energy collector.

In variations of either of the methods just described in which the external load is an electric power grid, the fault may include, for example, a voltage, current, or phase angle between voltage and current on the grid varying out of acceptable bounds, or the grid otherwise “going down”.

In another aspect, a heat and electricity providing system comprises at least a first solar energy collector and at least a first electrically powered heat pump. The solar energy collector includes a solar energy receiver, a reflector, and a tracker configured to orient the reflector, the receiver, or the reflector and the receiver to track motion of the sun in the sky so that solar radiation is concentrated by the reflector onto the receiver. The receiver includes one or more solar cells that, in operation of the solar energy collector, are illuminated by solar radiation concentrated by the reflector onto the receiver. The receiver also includes one or more fluid channels through which, in operation of the solar energy collector, a heat transfer fluid may pass to collect heat from solar radiation concentrated by the reflector onto the receiver.

The solar energy collector is fluidly coupled to an external source of the heat transfer fluid to be heated in the receiver, fluidly coupled to an external use or external user of the heat transfer fluid that has been heated in the receiver, and electrically coupled to deliver electric power generated by the receiver to an external load. The heat pump is fluidly coupled to a source of heat transfer fluid to be heated by the heat pump and fluidly coupled to the same external use or external user of heated heat transfer fluid as is the solar energy collector.

In some variations, the heat pump is fluidly coupled to the same external source of heat transfer fluid as is the solar energy collector.

In any of the above variations the heat pump may be electrically coupled to the solar energy collector to be powered by electric power generated by the solar energy collector.

Any of the above variations of the heat and electricity providing system may be configured so that a total heat requirement of the external use or external user of heat transfer fluid during a predetermined time period is satisfied by the combination of the total heat output delivered from the solar energy collector to the external use or external user during the predetermined time period and the total heat output delivered from the heat pump to the external use or external user during the predetermined time period, where the heat pump is powered during the predetermined time period by a total electric energy less than or equal to the total electric energy generated by the solar energy collector during the predetermined time period. In such variations, the total heat output delivered from the solar energy collector to the external use or external user during the predetermined time period may be equal, for example, to about one half of the total heat requirement of the external use or external user of heat during the predetermined time. The predetermined time period may be, for example, about one year.

Any of the above variations of the heat and electricity providing system may comprise at least a first integrated balance of system located proximate to the first solar energy collector. The integrated balance of system includes an inverter electrically coupled to the receiver to receive direct current from the solar energy collector and configured to convert the direct current to alternating current, and a heat transfer fluid control system configured to circulate a heat transfer fluid through the solar energy collector. The heat transfer fluid control system comprises a controller, a pump controlled by the controller, and a power supply electrically coupled to the inverter to receive alternating current electric power from the inverter. The power supply provides electric power to the controller and to the pump.

The controller may control operation of the heat pump.

The integrated balance of system may further include an alternating current electric power outlet electrically coupled to the inverter to provide alternating current from the inverter to an external load, a first heat transfer fluid inlet configured to receive heat transfer fluid from an external supply, a first heat transfer fluid outlet coupled to the receiver to provide heat transfer fluid received from the external supply to the solar energy collector, a second heat transfer fluid inlet coupled to the receiver to receive heat transfer fluid from the solar energy collector, and a second heat transfer fluid outlet configured to provide heat transfer fluid received from the solar energy collector to an external use or external user.

Any of the variations of the integrated balance of system summarized above with respect to the first aspect may be used in the heat and electricity providing system of this third aspect.

Local heat transfer fluid coolers and local heat transfer storage as summarized above with respect to the solar energy collector system of the second aspect may be similarly used in any of the above variations of the heat and electricity providing system of this third aspect.

A method of operating any of the above variations of the heat and electricity providing system may comprise controlling the operation of the heat pump based on an expected demand for heat and an expected availability of heat and electric power from the solar energy collector. Alternatively, or in addition, a method of operating any of the above variations of the heat and electricity providing system may comprise controlling the operation of the heat pump based on an expected demand for heat and on a record of prior heat and electric power output from the solar energy collector. The expected demand, expected availability, and prior records may be over a period of, for example, about a day, about a week, about a month, or about a year.

In another aspect, a heat providing system comprises at least a first solar thermal energy collector and at least a first heat pump. The solar thermal energy collector may be similar to the solar energy collectors summarized above, except for lacking solar cells. The solar energy collector is fluidly coupled to an external source of the heat transfer fluid to be heated in the receiver and fluidly coupled to an external use or external user of the heat transfer fluid that has been heated in the receiver. The heat pump is fluidly coupled to a source of heat transfer fluid to be heated by the heat pump and fluidly coupled to the same external use or external user of heated heat transfer fluid as is the solar energy collector.

Balance of system for the heat providing system may be provided by a module comprising the heat transfer control system portion of the integrated balance of system summarized above, powered by an external electric power source.

A method of operating the heat providing system may comprise controlling the operation of the heat pump based on an expected demand for heat and an expected availability of heat from the solar thermal energy collector. Alternatively, or in addition, a method of operating the heat providing system may comprise controlling the operation of the heat pump based on an expected demand for heat and on a record of prior heat output from the solar energy collector. The expected demand, expected availability, and prior records may be over a period of, for example, about a day, about a week, about a month, or about a year.

In any of the above aspects and any of their variations, the heat transfer fluid may comprise, for example, water, ethylene glycol, or a mixture thereof. Alternatively, the heat transfer fluid may comprise an oil. Any suitable heat transfer fluid may be used.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIGS. 1A and 1B show, respectively, a perspective view and an end-on view of an example solar energy collector system comprising two photovoltaic-thermal solar energy collectors and an integrated balance of system.

FIG. 2A and 2B show, respectively, a front perspective view and a rear view of an example heat transfer fluid control portion of an integrated balance of system.

FIG. 3 shows a perspective view of electronics in the example integrated balance of system of FIGS. 2A and 2B.

FIG. 4 shows a block diagram of an example integrated balance of system with two photovoltaic-thermal solar energy collectors.

FIG. 5 shows a block diagram of three example integrated balance of systems communicating wirelessly with each other and with a computer network.

FIG. 6 shows a schematic diagram of an example photovoltaic-thermal solar energy collector system comprising a photovoltaic-thermal solar energy collector, an integrated balance of system, an optional heat transfer fluid cooler, and an optional heat transfer fluid storage.

FIG. 7 shows a schematic diagram of an example photovoltaic-thermal solar energy collector system comprising two photovoltaic-thermal solar energy collectors, each with its own integrated balance of system.

FIG. 8 shows a schematic diagram of an example heat and electricity providing system comprising a photovoltaic-thermal solar energy collector, an integrated balance of system, and a heat pump.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention. As used in this specification and the appended claims, the singular forms “a”, “an”, and “the” include plural referents unless the context clearly indicates otherwise.

This specification discloses apparatus, systems, and methods by which solar energy may be collected to provide electricity, heat, or a combination of electricity and heat. Such apparatus, methods, and systems may comprise or use one or more photovoltaic-thermal solar energy collectors. A photovoltaic-thermal solar energy collector collects solar energy from which it generates electricity and also delivers useful heat for an external use or external user. A photovoltaic-thermal solar energy collector may use reflectors or other optics to concentrate solar energy onto one or more solar energy receivers, but such concentration of solar energy is not required. The electricity generating and heat collecting portions of the photovoltaic-thermal solar energy collector may be either integrated with each other or separated from one another. Suitable photovoltaic-thermal solar energy collectors may have the form, for example, of trough collectors, dish collectors, linear Fresnel collectors, or heliostat and central tower collectors.

Example photovoltaic-thermal solar energy collectors that may be employed with the apparatus, systems, and methods disclosed herein include the photovoltaic-thermal solar energy collectors disclosed in U.S. patent application Ser. No. 12/712,122 “1-Dimensional Concentrated Photovoltaic Systems”, filed Feb. 24, 2010; U.S. patent application Ser. No. 12/788,048 “Concentrating Solar Photovoltaic-Thermal System” filed May 26, 2010; U.S. patent application Ser. No. 12/622,416 “Receiver For Concentrating Solar Photovoltaic-Thermal System filed Nov. 19, 2009; U.S. patent application Ser. No. 12/774,436 “Receiver For Concentrating Solar Photovoltaic-Thermal System” filed May 5, 2010; U.S. patent application Ser. No. 12/781,706 “Concentrating Solar Energy collector” filed May 17, 2010; and U.S. patent application Ser. No. 13/079,193 “Concentrating Solar Energy Collector” filed Apr. 4, 2011, each of which is incorporated herein by reference in its entirety.

One apparatus described herein in several variations is an integrated balance of system for one or more photovoltaic-thermal solar energy collectors. As used herein with reference to a photovoltaic-thermal solar energy collector system comprising a photovoltaic-thermal solar energy collector, “balance of system” generally refers to components of the system other than the photovoltaic-thermal solar energy collector. Such additional components include, for example, an inverter that converts direct current electricity generated by photovoltaic cells in the photovoltaic-thermal solar energy collector to alternating current. The inverter may also control the current-voltage point at which the photovoltaic cells operate in order to maximize electric power output from the photovoltaic-thermal solar energy collector. Balance of system as used herein also includes a heat transfer fluid control system, and related components, that circulates a heat transfer fluid through the solar energy collector to collect heat. In variations in which the heat transfer fluid comprises water, this portion of the balance of system may be referred to as the “hydronics”.

The integrated balance of system described herein electrically integrates the inverter with the heat transfer control system. Optionally, the inverter is physically integrated with the heat transfer control system as well. The integrated balance of system may be modular and may have a relatively small footprint compared to the rest of the system. “Footprint” as used herein refers to the surface area covered by the integrated balance of system module when installed and integrated with one or more solar energy collectors.

One system described herein in several variations is a photovoltaic-thermal solar energy collector system comprising one or more integrated balance of system modules as disclosed herein and one or more photovoltaic-thermal solar energy collectors. Such a system may comprise, for example, 1, 2, between 2 and 10, between 10 and 20, between 20 and 30, or any other number of photovoltaic-thermal solar energy collectors suitable to serve an intended use or user of the heat and electricity generated by the system. Each photovoltaic-thermal solar collector may comprise for example, a row of coupled photovoltaic-thermal solar energy collector modules. The system may comprise, for example, a separate integrated balance of system for each photovoltaic-thermal solar energy collector, one integrated balance of system per pair of photovoltaic-thermal solar energy collectors, or any other suitable grouping of photovoltaic-thermal solar energy collectors with integrated balance of system modules.

In such systems, the electrical and thermal operation of individual photovoltaic-thermal solar energy collectors, or of different groups of photovoltaic-thermal solar energy collectors, may be separately controlled by different integrated balance of system modules. Consequently, different photovoltaic-thermal solar energy collectors may operate at different current-voltage power points, use different heat transfer fluid flow rates and temperatures, or both operate at different current-voltage power points and use different heat transfer fluid flow rates and temperatures. Such a system may accommodate, for example, two or more photovoltaic-thermal solar energy collectors that have different electric power and heat production capacities because they comprise different numbers of substantially identical photovoltaic-thermal solar collector modules (i.e., because they have different row lengths).

Another system described herein in several variations is a heat and electricity providing system comprising a photovoltaic-thermal solar energy collector and an electrically powered heat pump. A heat pump is an apparatus that pumps (moves) heat from a heat source to a higher temperature heat sink. Such a heat pump may be used to heat a heat transfer fluid to some desired temperature for an external use or external user.

In the heat and electricity providing systems described herein, the heat pump may be powered from an external electric power grid or, optionally, by the electric power output from the photovoltaic-thermal solar energy collector. Electric power generated by the photovoltaic-thermal solar energy collector that is not supplied to the heat pump may be, for example, supplied to the external electric power grid or to some other external load. The heat pump and the photovoltaic-thermal solar energy collector may operate in parallel to simultaneously deliver heat to the same external use or external user. This may occur, for example, when heat output from the photovoltaic-thermal solar energy collector is insufficient, or expected to be insufficient, to meet a heat requirement of the external use or external user. In such instances the heat pump may be powered from the external power grid, by the electric power output of the photovoltaic-thermal solar energy collector, or by both. In addition, the heat pump may be powered from the external electric power grid to deliver heat to the external use or external user at times (e.g., at night, during cloudy days or bad weather) when the photovoltaic-thermal solar energy collector is not operating.

Operation of the heat pump may be controlled based on an expected demand for heat and an expected or current availability of heat (and, optionally, electric power) from the photovoltaic-thermal solar energy collector. For example, if the demand for heat over some upcoming time period is expected to exceed that available from the photovoltaic-thermal solar energy collector, the heat pump may be operated during and before that period to ensure a sufficient supply of heat. Alternatively, or in addition, operation of the heat pump may be controlled based on an expected demand for heat and a record of (e.g., recent) prior heat (and, optionally, electric power) production by the photovoltaic-thermal solar energy collector. For example, if heat production by the photovoltaic-thermal solar energy collector is falling short of satisfying an expected upcoming demand for heat, the heat pump may be operated to make up for the short-fall.

The performance of a heat pump may be characterized by its “coefficient of performance” (COP), which is the ratio of the heat pumped by the heat pump to the amount of work required to pump the heat. For electrically powered heat pumps, the COP is essentially the amount of heat pumped by the heat pump divided by the amount of electric energy required by the heat pump to pump that heat. In addition, the work dissipated in the heat pump can also appear as heat in the heated heat transfer fluid. Thus the total amount of heat delivered by an electrically powered heat pump to a heat transfer fluid may be approximately equal to the amount of electric energy used to pump the heat multiplied by (COP+1), i.e., the heat delivered is˜(COP+1)×(electric energy used to pump the heat).

For electrically powered heat pumps pumping ambient heat into a heat transfer fluid (e.g., water) having a maximum temperature of about 100° C., the value of the COP may be, for example about 3 or larger. The ratio of heat energy output to the electric energy output from a photovoltaic-thermal solar energy collector may be, in some variations, about 4. If the electric output of the photovoltaic-thermal solar energy collector (or an equivalent amount of electric energy drawn from an external electric power grid) is used to power the heat pump, the total heat production of the system may be approximately 4 units of heat from the photovoltaic-thermal solar energy collector plus about 4 units of heat from the heat pump. Thus a heat and electricity providing system as disclosed herein may provide approximately twice the heat output of the photovoltaic-thermal solar energy collector alone. That is, use of a heat pump as disclosed herein may double or nearly double the heat production from solar energy.

The photovoltaic-thermal solar energy collector and the heat pump may be selected to have sizes and/or output capacities such that together the photovoltaic-thermal solar energy collector and the heat pump satisfy the heat requirements of the external use or external user year round (or over some other period of time), despite the varying availability of solar energy. Further, the sizes and/or capacities of the photovoltaic-thermal solar energy collector and the heat pump may be selected so that the total electric energy requirement of the heat pump during the year (or over some other time period) is less than or equal to the total electric power output from the photovoltaic-thermal solar energy collector during that period. In such cases, the system may meet a “net zero” standard under which the total renewable (e.g., solar) energy output of the system is greater than or equal to the total amount of heat delivered to the external use or external user.

In operation of such a “net zero” system, the photovoltaic-thermal solar energy collector may deliver its electric output to an external electric power grid, to the heat pump, or to both. Similarly, the heat pump may be powered by the photovoltaic-thermal solar energy collector, the external electric power grid, or both. The system is “net zero” because the total electric energy used by the heat pump, of whatever origin, is less than or equal to the total electric power output of the photovoltaic-thermal solar energy collector to the grid and the heat pump.

As described in more detail below, some variations of the heat and electricity providing systems disclosed herein include an integrated balance of system. Such inclusion of an integrated balance of system is not required, however.

Although the combination of a solar energy collector and heat pump has been described so far as a “heat and electricity providing system”, in some variations a heat pump is combined with a solar thermal energy collector that does not generate electricity. Such “heat providing systems” still benefit, as described above, from the ability to operate the heat pump during periods when the solar energy collector is not providing heat or is not providing sufficient heat for current or expected demand. Suitable solar thermal energy collectors may be similar to any of the photovoltaic-thermal solar energy collectors described herein, except that the solar thermal energy collectors lack solar cells. The heat transfer control system module of the integrated balance of system described herein, powered by an external electric power source, may serve as balance of system for such solar thermal energy collectors.

In a similar manner as in the heat and electric power providing system, operation of the heat pump in the heat providing system may be controlled based on an expected demand for heat and an expected or current availability of heat from the solar-thermal energy collector. Alternatively, or in addition, operation of the heat pump may be controlled based on an expected demand for heat and a record of (e.g., recent) prior heat production by the solar thermal energy collector.

Methods of operating the integrated balance of system, photovoltaic-thermal solar energy collector system, and heat and electricity providing system are also disclosed herein.

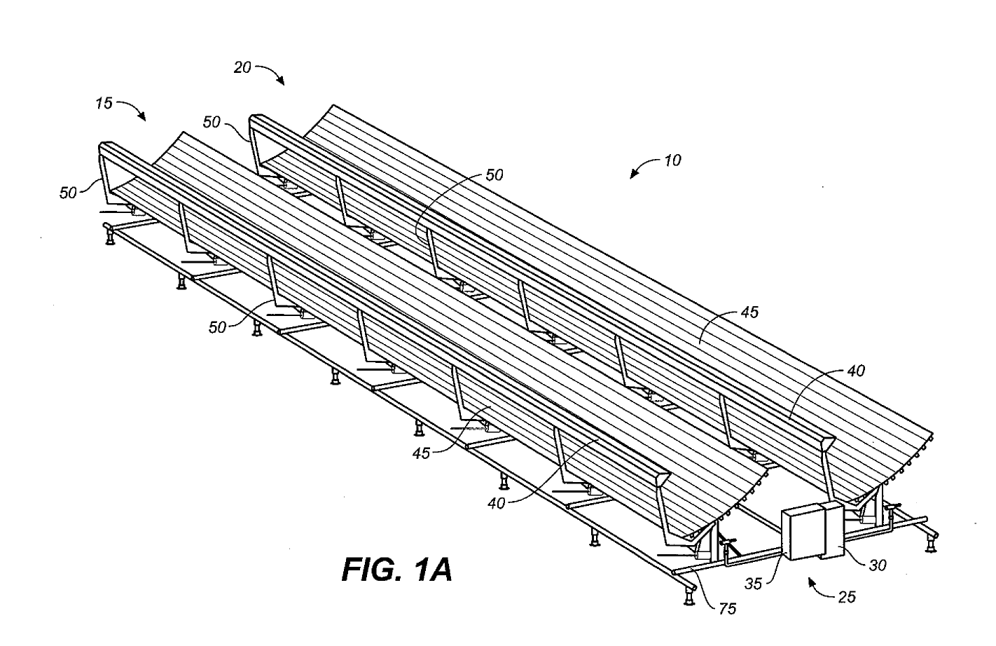

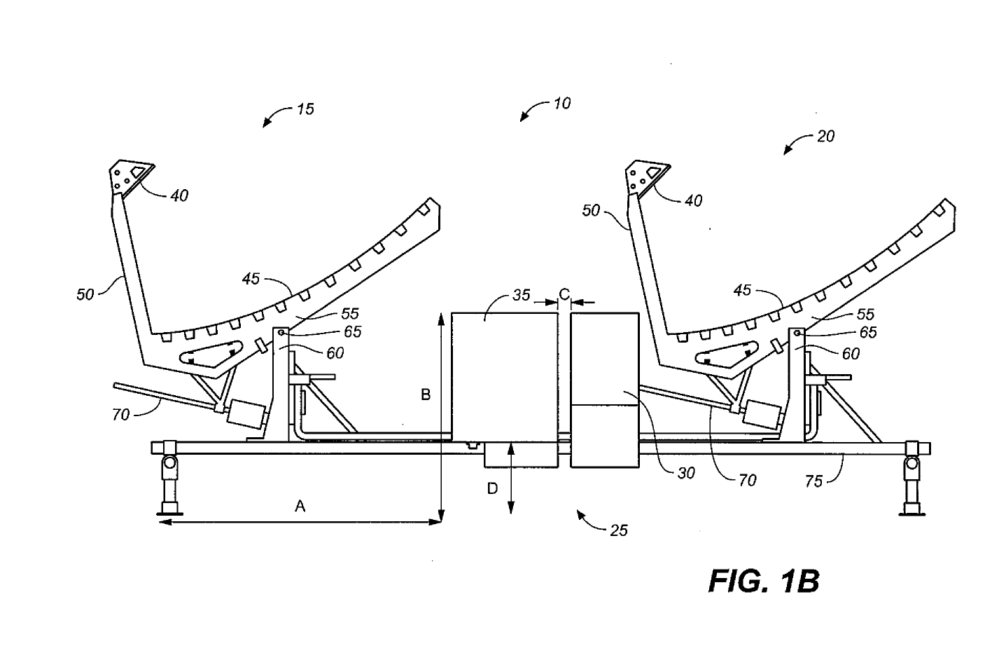

Referring now to FIGS. 1A and 1B, an example solar energy collector system 10 comprises a first photovoltaic-thermal solar energy collector 15, a second photovoltaic-thermal solar energy collector 20, and an integrated balance of system 25 comprising an inverter module 30 and a heat transfer control system module 35.

In the illustrated example, each of the photovoltaic-thermal solar energy collectors comprise a photovoltaic-thermal solar energy receiver 40, a reflector 45, receiver supports 50 supporting the receiver above the reflector, and support structure 55 supporting the reflector and the receiver and pivotally mounted to vertical supports 60 at pivot point 65. Vertical supports 60 are mounted to rack 75, which may be configured to support the photovoltaic solar energy collectors above any suitable surface at, for example, approximately ground level or on a roof top. In operation, linear actuators 70 rotate receiver 40, reflector 45, and support structure 55 about pivot point 65 to track the sun so that reflector 45 concentrates solar radiation to an approximately linear focus on receiver 40 along the receivers long axis. (Support structure 55, vertical supports 60, and linear actuators 70 may be viewed as elements of a “tracker” as that term is used elsewhere herein). Each receiver 40 comprises photovoltaic cells on its reflector-facing surface as well as one or more fluid channels, extending the length of the receiver, through which heat transfer fluid may be circulated to collect heat. Each of the illustrated photovoltaic-thermal solar energy collectors comprises and is assembled from six receiver/reflector/support modules, the length of which is defined approximately by the distance between receiver supports 50. Any other suitable photovoltaic-thermal solar energy collectors may be used in place of the illustrated examples.

In the illustrated example, the integrated balance of system 25 is also mounted to rack 75 at one end of the photovoltaic-thermal solar energy collectors. Any other suitable placement and mounting of integrated balance of system 25 may be used instead.

The heat transfer control system module 35 of integrated balance of system 25 may have, for example, a height of approximately 610 millimeters, a width of approximately 508 millimeters, and a depth of approximately 254 millimeters. Inverter module 30 may have for example, a height of approximately 615 millimeters, a width of approximately 470 millimeters, and a depth of approximately 240 millimeters. These dimensions allow the modules to be easily shipped in prefabricated form, and then easily handled for on-site installation with the photovoltaic-thermal solar energy collectors. Any other suitable dimensions may also be used. In some variations the inverter module 30 and heat control transfer system module 35 may be physically integrated and share, for example, a single enclosure. As noted above, the total footprint of the integrated balance of system, including both the inverter module and the heat transfer fluid control module, may be, for example, less than about 1.0 square meters, less than about 0.8 square meters, less than about 0.5 square meters, less than about 0.3 square meters, or less than about 0.25 square meters.

The relatively small foot print of the integrated balance of system may be understood by contrast to the size of a photovoltaic-thermal solar energy collector. In the illustrated example of FIGS. 1A and 1B, for example, a photovoltaic-thermal solar energy collector comprising six collector modules as shown has a length of about 17 meters and a width of about 1.5 meters. For further comparison, additional example dimensions are provided in FIG. 1B: distance A is about 1320 millimeters, distance B is about 968 millimeters, distance C is about 50 millimeters, and distance D is about 355 millimeters. Any of these distances may be altered as suitable.

Inverter module 30 may be or comprise, for example, any suitable commercially available inverter. Suitable inverters may include, for example, a Sunny Boy 5000-US inverter available from SMA Solar Technology AG.

Electric and heat transfer fluid connections between integrated balance of system 25 and photovoltaic-thermal solar energy collectors 15 and 20 as described below, for example, are not explicitly shown in FIGS. 1A and 1B. Any suitable configuration of conduits and wiring may be used to accomplish such connections.

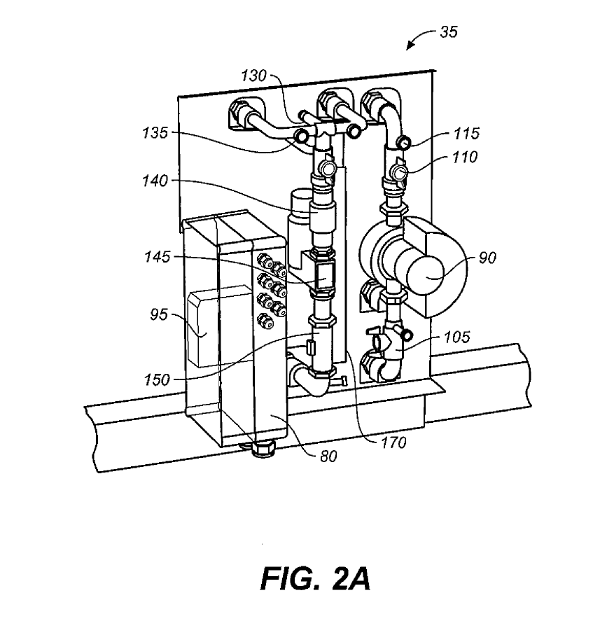

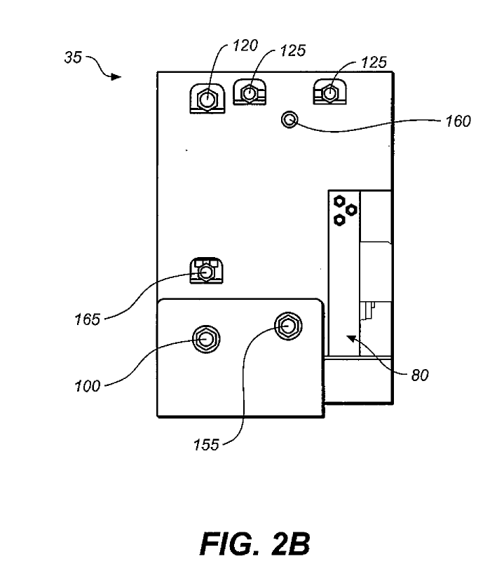

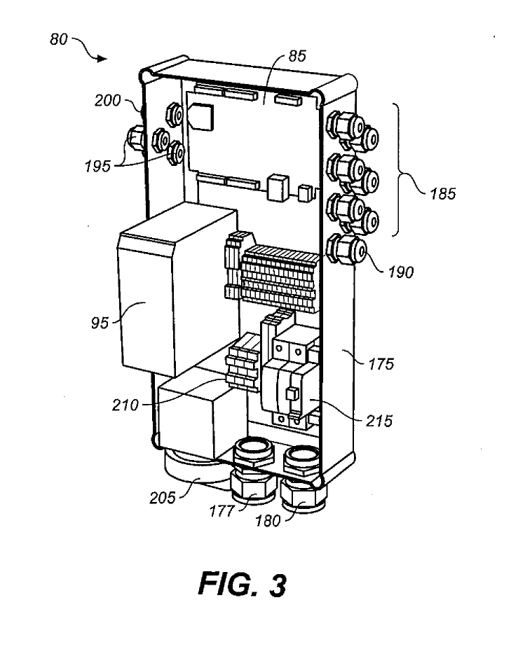

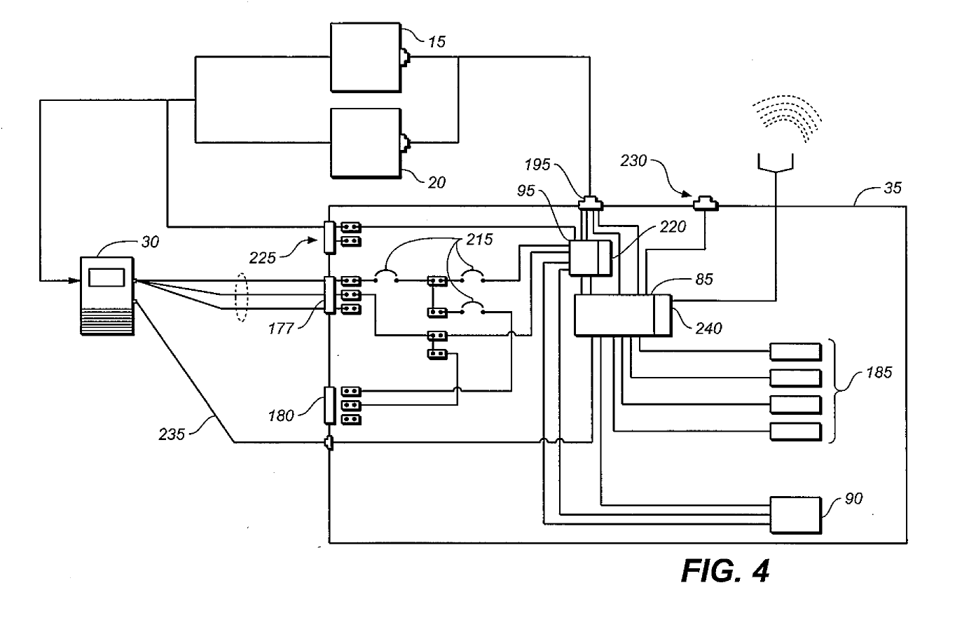

Referring now to FIGS. 2A (front) and 2B (back), an example heat transfer fluid control system module 35 comprises a controller 85 (in electronics 80, shown in greater detail in FIG. 3), a pump 90 controlled by the controller, and a power supply 95 (also in electronics 80) that provides electric power to controller 85 and to pump 90. As further described below with respect to the block diagram of FIG. 4, the power supply is electrically coupled to inverter module 30 to receiver alternating current electric power from the inverter.

Heat transfer fluid from an external source enters heat transfer fluid control system module 35 through heat transfer fluid inlet 100, passes through optional isolation and fill valve 105, is pumped by pump 90, passes through optional isolation valve 110 and past optional temperature and pressure sensors 115, then exits heat transfer fluid control system module 35 through heat transfer fluid outlet 120 to circulate through one or more photovoltaic-thermal solar energy collectors. Heat transfer fluid returning from the one or more photovoltaic-thermal solar energy collectors reenters heat transfer fluid control system module 35 through heat transfer fluid inlets 125, passes by optional pressure release valve 130 and past optional temperature sensor 135, and passes through optional check valve 140 and optional air separator 145 and past optional flow and temperature sensors 150 to exit heat transfer fluid control system module 35 through heat transfer fluid outlet 155 to an external use or external user of the collected heat. Any fluid released by pressure release valve 130 may exit through outlet 160. Optional heat transfer fluid inlet 165 may be coupled to an external tank, for example. Optional cable raceway 170 accommodates, for example, cables (not shown) providing electric power to the pump or to trackers in the photovoltaic-thermal solar energy collectors, or cables coupling sensors 115, 135, or 150 to controller 85. Any other suitable configuration of these or similar components may be used.

Referring now to FIG. 3, electronics 80, enclosed in enclosure 175, comprise controller 85 and power supply 95 as noted above. In addition, in the illustrated example electronics 80 comprises an alternating current electric power inlet 177 for receiving power from inverter module 30, and an alternating current electric power outlet 180 for providing alternating current electric power from inverter module 30 to an external load, such as to an external electric power grid. Signal ports 185, coupled to controller 85, enable controller 85 to receive signals from temperature and pressure sensors such as sensors 115, 135, and 150, for example, and to provide control signals to pump 90. Electrical outlet 190 provides electric power to pump 90. Signal/power ports 195 enable controller 85 to provide control signals to or receive data signals (information) from one or more trackers, and also enable power supply 95 to supply electric power to the trackers. The control and data signals may use an RS-232 standard, for example. Internet port 200 provides an optional wired internet connection to controller 85. Disconnect 205 may be used to disconnect integrated balance of system 25 from the external load (e.g., from an external electric power grid). Grid field connections 210 are electrically coupled to alternating current electric power inlet 177 and to alternating current electric power outlet 180 to provide for the electrical connection of the inverter module 30 to an external load such as an external electric power grid. Circuit breakers 215 break the connection between the inverter and the external load in the event of a fault condition.

In the illustrated example, the alternating current electric power outlet satisfies the American National Standards Institute National Electrical Code NFPA 70 (edition effective Aug. 25, 2010) and the heat transfer fluid inlets and outlets (e.g., fittings) satisfy the American National Standards Institute National Tapered Pipe Thread standard B1.20.1 (edition effective Aug. 31, 1983, reaffirmed in 2001).

Generally any suitable components may be used in integrated balance of system 25. Controller 85 may be or comprise, for example, a BL4S150 Series single-board computer available from Digi International, Inc. Pump 90 may be or comprise, for example, a Grundfos MAGNA GEO variable speed pump available from Grundfos Holding A/S. Power supply 95 may be or comprise, for example, a WDR-120-24 wide range 24VDC power supply available from Mean Well USA, Inc. Power supply 95 may be or comprise, for example, an uninterruptible power supply with compatible rechargeable batteries.

FIG. 4 shows a block diagram of the electrical connections within an example integrated balance of system operating with two photovoltaic-thermal solar energy collectors. Much of the block diagram of FIG. 4 may be understood based on the discussion above with respect to FIGS. 1A, 1B, 2A, 2B, and 3. In addition to components and connections previously discussed, the block diagram of FIG. 4 shows power supply 95 including optional local electric storage 220 which may be, for example, one or more batteries. The block diagram further shows power supply 95 optionally electrically coupled, through direct current electric power inlet 225, to direct current electric power output by photovoltaic-thermal solar energy collectors 15 and 20.

When present, these alternative sources of electric power to power supply 95 allow it to switch from operating on alternating current electric power provided by inverter module 30 to operating on direct current electric power from storage, direct current electric power from the photovoltaic-thermal solar energy collectors, or direct current electric power from both storage and from the photovoltaic-thermal solar energy collectors, if alternating current electric power from the inverter becomes unavailable. For example, power supply 95 may switch to one or both of the direct current electric power sources if a fault on an electric load connected to alternating current outlet 180 trips one or more of circuit breakers 215. If alternating current outlet 180 is coupled to the external electric power grid, the fault may be the grid “going down”. Alternatively, or in addition, inverter module 30 may shut down alternating current output from the inverter upon the occurrence of a fault such as the electric grid going down.

In the event of a fault on the external electric load, and the inverter consequently ceasing to provide alternating current electric power, the integrated balance of system may use back-up direct current power provided as described above to power the trackers in the associated photovoltaic-thermal solar energy collectors to reorient the trackers to reduce or stop concentrating solar radiation onto the solar energy collectors' receivers. Alternatively, in the event of a fault on the external electric load, and the inverter consequently ceasing to provide alternating current electric power, the integrated balance of system may use back-up direct current power provided as described above to power its pump to continue circulating heat transfer fluid through the receivers, and to power the trackers to continue concentrating solar radiation onto the receivers, to thereby continue producing heated heat transfer fluid for the external use or external user.

Referring again to FIG. 4, controller 85 may control the flow rate of heat transfer fluid through photovoltaic-thermal solar energy collectors 15 and 20 so that the heat transfer fluid returning from the photovoltaic-thermal solar energy collectors has been heated to a desired temperature. The temperature of the returning heat transfer fluid may be measured within the integrated balance of system by temperature sensor 135 (FIG. 2B) for example, coupled to controller 85. Controller 85 may control the flow rate of heat transfer fluid by, for example, controlling the speed of variable speed pump 90. Controller 85 may also monitor the pressure of the heat transfer fluid with a pressure sensor (e.g., placed at the same location as temperature sensor 115) and reduce or increase the flow rate as necessary to maintain the pressure within a desired range.

The heat collected by the heat transfer fluid as it passed through the photovoltaic- thermal solar energy collectors may be estimated by comparing its temperature as measured upon its exit from the integrated balance of system (e.g., by temperature sensor 115, FIG. 3) to pass through the photovoltaic-thermal solar energy collectors to its temperature upon returning to the integrated balance of system.

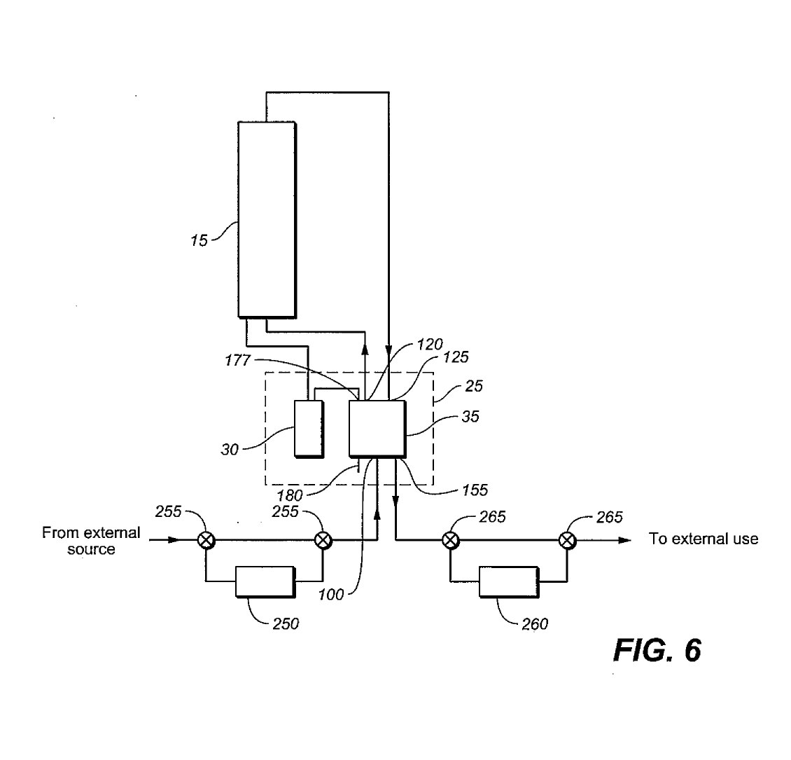

Controller 85 may also control external control valves through optional communication port 230. Such control valves may be used, for example, to route heat transfer fluid through a cooler or cooling system prior to its entrance into the integrated balance of system. The controller may take this action, for example, if the temperature of the heat transfer fluid prior to dispatch to the photovoltaic-thermal solar energy collectors, as measured by temperature sensor 115, for example, exceeds some threshold. Such variations are further discussed below with respect to FIG. 6.

The block diagram of FIG. 4 also shows inverter module 30 optionally coupled to controller 85 by communication line 235, by which inverter module 30 can provide information about its operation to controller 85 and by which controller 85 may provide control signals to inverter module 30.

In addition, the block diagram of FIG. 4 shows controller 85 including optional wireless communicator (e.g., radio, wireless device) 240. Any other suitable incorporation of a wireless communicator may also be used. Inclusion of wireless communicator 240 allows for wireless remote diagnostics and control of inverter module 30 and of heat transfer control system module 35. Information communicated wirelessly by integrated balance of system 25 can include, for example, temperatures, pressures, and flow rates of the heat transfer fluid, and information about operation of the inverter such as the operating maximum power point current and voltage. In addition, controller 85 may wirelessly receive control commands directing it, for example, to provide heat transfer fluid at a particular temperature at the output of the integrated balance of system to the intended use, or to operate control valves via communication port 230. (Optional wired internet communication as shown in FIG. 3 may alternatively or additionally be used to accomplish the above purposes).

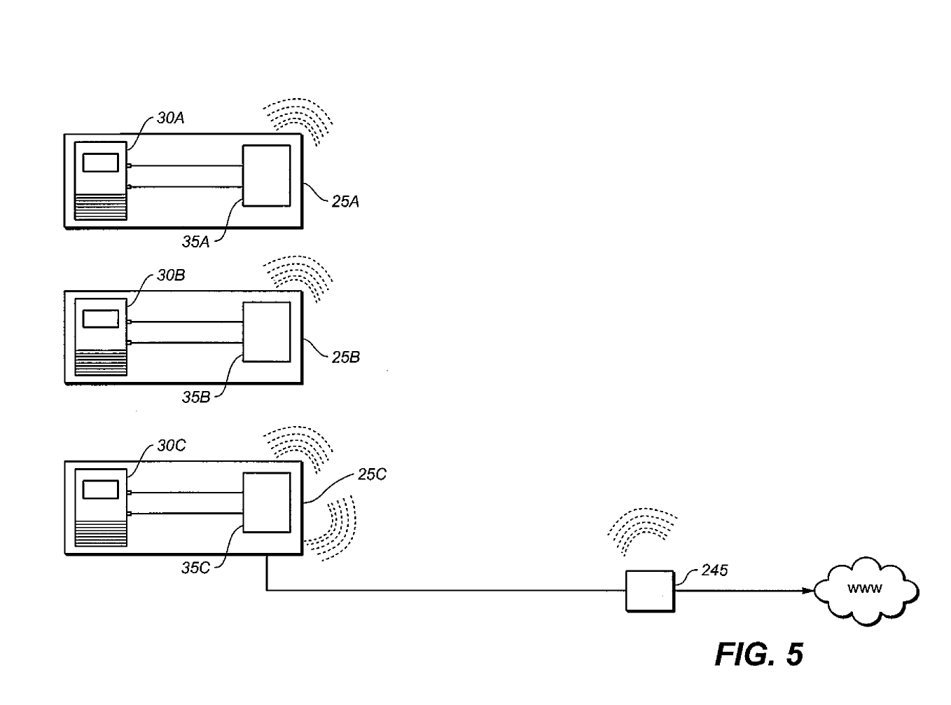

Referring now to FIG. 5, two or more integrated balance of systems (e.g., 25A, 25B, and 25C comprising inverter modules 30A, 30B and 30C and heat transfer control system modules 35A, 35B, and 35C) may be configured to communicate with each other wirelessly. One or more of the integrated balance of systems (e.g., 25C) may also be configured to communicate wirelessly and/or by wired internet with an internet-enabled computer, server, or other control device 245. Information to be communicated to server 245 by a particular integrated balance of system may first be transferred through one or more other integrated balance of systems until it reaches a “master” integrated balance of system configured to communicate with server 245. In a similar manner, control commands sent by server 245 to a particular integrated balance of system may reach the intended integrated balance of system via other integrated balance of systems.

Referring now to FIG. 6, as noted above a photovoltaic-thermal solar energy collector system may comprise an optional heat transfer fluid cooler, an optional heat transfer fluid storage, or both. In the illustrated example, heat transfer fluid from an external source may be routed through cooler 250, or routed to bypass cooler 250, by valves 255. Valves 255 may be controlled, for example, by the controller in integrated balance of system 25. Cooler 250 may be used to cool incoming heat transfer fluid when, for example, the temperature of the heat transfer fluid exceeds some threshold. Similarly, heated heat transfer fluid exiting integrated balance of system 25 may be routed into local storage 260, or routed to bypass local storage 260, by valves 265. Valves 265 may also be controlled, for example, by the controller in integrated balance of system 25. Storage 260 may be used, for example, if heat production in the photovoltaic-thermal solar energy collector exceeds the current need of the external use or external user.

Though FIG. 6 shows particular fluid circuits serving cooler 250 and storage 260, any suitable fluid circuit using any suitable number of valves may be used instead. Also, though FIG. 6 shows one integrated balance of system serving one photovoltaic-thermal solar energy collector, other similar systems may include more than one integrated balance of system with each serving one or more photovoltaic-thermal solar energy collectors. Each integrated balance of system may optionally be coupled to its own cooler, local storage, or both. In some variations, a cooler or a local storage may serve two or more integrated balance of systems.

Cooler 250 may be, for example, a 32 kW gForce Fluid Cooler, model GFC-03234, available from Data Aire, Inc. Storage 260 may comprise, for example, one or more metal or plastic tanks and have a total volume, for example, of about 300 gallons to about 500 gallons, though any other suitable volume may instead by used. Storage 260 may be located, for example, adjacent to the integrated balance of system or solar energy collector, under racking supporting the solar energy collector (see, e.g., racking 75 in FIG. 1A), or in any other suitable location. Storage 260 located under racking supporting the solar energy collector may hang from or otherwise also be supported or partially supported by the racking.

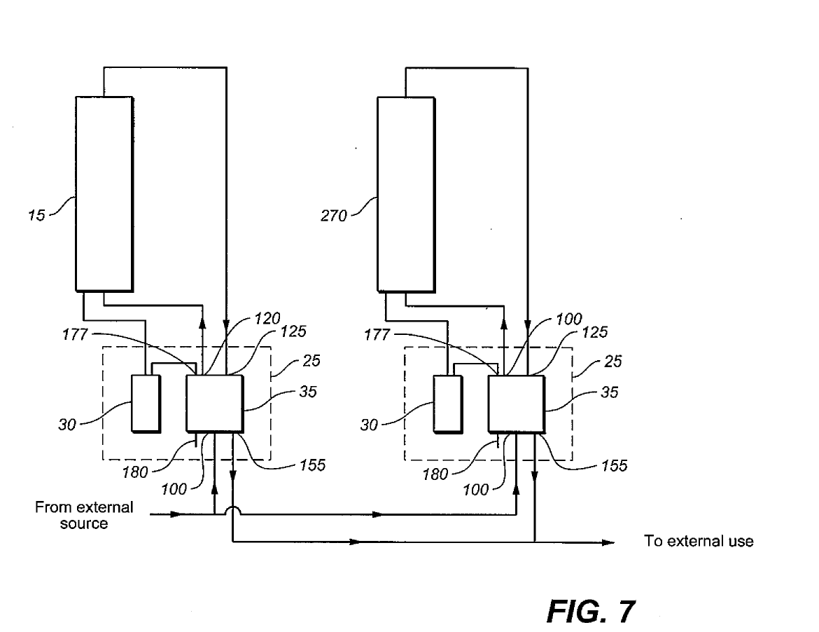

Referring now to FIG. 7, as noted above a photovoltaic-thermal solar energy collector system may comprise two or more photovoltaic-thermal solar energy collectors (e.g., 15 and 270) each coupled to its own integrated balance of system 25. Similar systems may include two or more groups of photovoltaic-thermal solar energy collectors (e.g., a pair of collectors to a group), with each group coupled to its own integrated balance of system. The two or more integrated balance of systems may be coupled to the same external source of heat transfer fluid (as shown) or to different sources. In either case, the integrated balance of systems may be coupled to the same external use or external user of heat (as shown), or to different external uses or external users. Each integrated balance of system may control the current-voltage power point and the heat transfer fluid flow rate and temperature of its photovoltaic-thermal solar energy collector (or group) independently of the other photovoltaic-thermal solar energy collectors. This independent control may allow better optimization of electric power generation and heat production from the system.

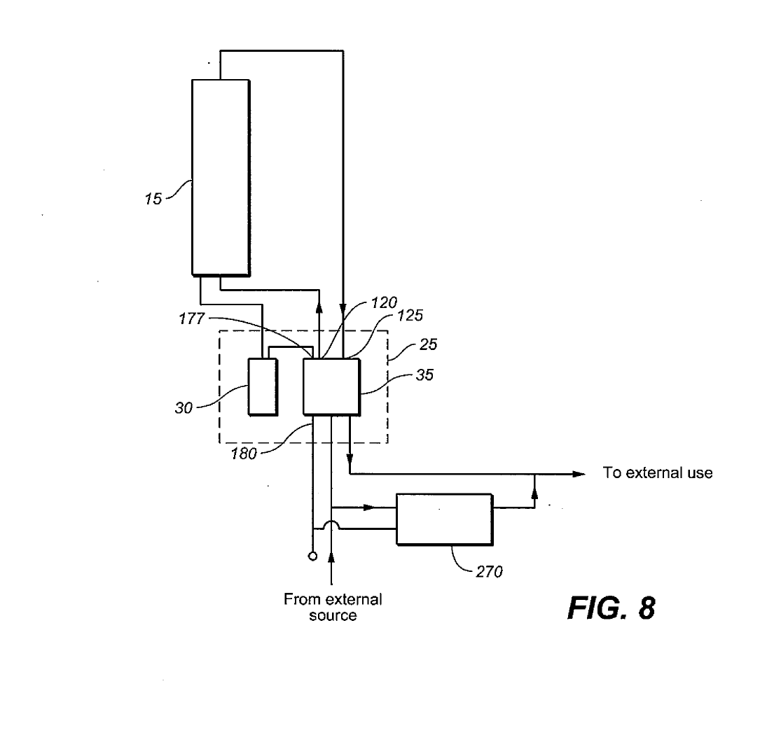

Referring now to FIG. 8, also as noted above a heat and electricity providing system may comprise a photovoltaic-thermal solar energy collector 15 and a heat pump 270 each configured to provide heat to the same external use or external user. The heat pump may be powered by electric power generated by the photovoltaic-thermal solar energy collector, by externally provided electric power, or by both. The heat pump may be, for example, a Danfoss Atec 11 heat pump available from Danfoss A/S.

In the illustrated example, the system also includes an integrated balance of system 25 as disclosed herein. The integrated balance of system may optionally control the operation of the heat pump. Use of such an integrated balance of system in the heat and electricity providing system is optional. Any suitable control system and/or balance of system may be used to serve the heat pump and the photovoltaic-thermal solar energy collector. Also, the illustrated example shows the heat pump and the photovoltaic thermal solar energy collector coupled to the same external source of heat transfer fluid. The heat pump and photovoltaic-thermal solar energy may instead by coupled to different source of heat transfer fluid. Further, though FIG. 8 shows only one photovoltaic-thermal solar energy collector and only one heat pump, other similar heat and electricity providing systems may include more than one photovoltaic-thermal solar energy collector, more than one heat pump, or more than one photovoltaic-thermal solar energy collector and more than one heat pump. Any suitable combination of photovoltaic-thermal solar energy collectors and heat pumps may be used.

This disclosure is illustrative and not limiting. Further modifications will be apparent to one skilled in the art in light of this disclosure and are intended to fall within the scope of the appended claims.

What is claimed is:

1. An integrated balance of system for a photovoltaic-thermal solar energy collector, the integrated balance of system comprising:
an inverter configured to convert direct current received from the solar energy collector to alternating current;
a heat transfer fluid control system including a controller, a pump controlled by the controller, and a power supply electrically coupled to the inverter to receive alternating current electric power from the inverter, the power supply providing electric power to the controller and to the pump, the heat transfer fluid control system configured to circulate a heat transfer fluid through the solar energy collector;
an alternating current electric power output electrically coupled to the inverter to provide alternating current from the inverter to an external load;
a first heat transfer fluid inlet configured to receive heat transfer fluid from an external supply;
a first heat transfer fluid outlet configured to provide heat transfer fluid received from the external supply to the solar energy collector;
a second heat transfer fluid inlet configured to receive heat transfer fluid from the solar energy collector; and
a second heat transfer fluid outlet configured to provide heat transfer fluid received from the solar energy collector to an external use or external user.

2. The integrated balance of system of claim 1, configured as one or more prefabricated portable modules shippable to a site of the solar energy collector for integration with the solar energy collector.

3. The integrated balance of system of claim 2, wherein the one or more modules have a total footprint with an area less than about 0.8 square meters.

4. The integrated balance of system of claim 3, wherein the alternating current electric power outlet satisfies the American National Standards Institute National Electrical Code NFPA 70 and the heat transfer fluid inlets and outlets satisfy the American National Standards Institute National Tapered Pipe Thread standard B1.20.1.

5. The integrated balance of system of claim 1, wherein the power supply is configured to switch from operating on alternating current provided by the inverter to operating on direct current provided by local electric power storage if alternating current electric power from the inverter becomes unavailable.

6. The integrated balance of system of claim 1, wherein the power supply is configured to switch from operating on alternating current provided by the inverter to operating on direct current generated by the solar energy collector if alternating current electric power from the inverter becomes unavailable

7. The integrated balance of system of claim 1, wherein the power supply is configured to provide electric power to the solar energy collector to power a tracker that adjusts an orientation of the solar energy collector to track the sun as it moves across the sky.

8. The integrated balance of system of claim 7, wherein the power supply is configured to switch from operating on alternating current provided by the inverter to operating on direct current generated by the solar energy collector if alternating current electric power from the inverter becomes unavailable.

9. The integrated balance of system of claim 1, wherein the controller is coupled to the inverter to receive signals from the inverter comprising information about the operation of the inverter.

10. The integrated balance of system of claim 1, wherein the pump is a variable speed pump with speed controlled by the controller depending on a temperature of the heat transfer fluid.

11. The integrated balance of system of claim 10, wherein the temperature of the heat transfer fluid is measured after the heat transfer fluid has been heated in the solar energy collector and prior to being supplied to the external use or external user.

12. The integrated balance of system of claim 1, comprising a wireless communicator coupled to the controller to receive signals from the controller and configured to communicate with another substantially similar integrated balance of system.

13. The integrated balance of system of claim 1, comprising a wireless communicator coupled to the controller to receive signals from the controller and configured to communicate with a computer.

14. A solar energy collector system comprising:
at least a first solar energy collector including:
a solar energy receiver;
a reflector; and
a tracker configured to orient the reflector, the receiver, or the reflector and the receiver to track motion of the sun in the sky so that solar radiation is concentrated by the reflector onto the receiver;
wherein the receiver includes one or more solar cells that, in operation of the solar energy collector, are illuminated by solar radiation concentrated by the reflector onto the receiver, and the receiver also includes one or more fluid channels through which, in operation of the solar energy collector, heat transfer fluid may pass to collect heat from solar radiation concentrated by the reflector onto the receiver; and
at least a first integrated balance of system located proximate to the first solar energy collector and including:
an inverter electrically coupled to the receiver to receive direct current from the solar energy collector and configured to convert the direct current to alternating current;
a heat transfer fluid control system including a controller, a pump controlled by the controller, and a power supply electrically coupled to the inverter to receive alternating current electric power from the inverter, the power supply providing electric power to the controller and to the pump, the heat transfer fluid control system configured to circulate a heat transfer fluid through the solar energy collector;
an alternating current electric power output electrically coupled to the inverter to provide alternating current from the inverter to an external load;
a first heat transfer fluid inlet configured to receive heat transfer fluid from an external supply;
a first heat transfer fluid outlet coupled to the receiver to provide heat transfer fluid received from the external supply to the solar energy collector;
a second heat transfer fluid inlet coupled to the receiver to receive heat transfer fluid from the solar energy collector; and
a second heat transfer fluid outlet configured to provide heat transfer fluid received from the solar energy collector to an external use or external user.

15. The solar energy collector system of claim 14, comprising local heat transfer fluid storage fluidly coupled to the second heat transfer outlet.

16. The solar energy collector system of claim 14, comprising a local heat transfer fluid cooler fluidly coupled to the first heat transfer fluid inlet and configured to receive heat transfer fluid from the external supply.

17. The solar energy collector system of claim 16, wherein the controller controls one or more valves to bypass the heat transfer fluid cooler or to route heat transfer fluid from the external supply through the heat transfer fluid cooler prior to the heat transfer fluid entering the first heat transfer fluid inlet, the controller controlling the one or more valves based on a temperature of the heat transfer fluid.

18. The solar energy collector system of claim 14, wherein the power supply provides electric power to the solar energy collector to power the tracker;

19. The solar energy collector system of claim 18, wherein the power supply receives direct current electric power generated by the solar energy collector.

20. The solar energy collector system of claim 19, wherein the receiver includes solar cells that generate sufficient direct current electric power under a solar irradiance of about 30 Watts per square meter of solar cell to power the tracker.

21. A method of operating the solar energy collector system of claim 18, comprising:
detecting a fault on the external load;
ceasing to provide alternating current from the inverter to the external load; and
powering the tracker from the power supply to orient the reflector, the receiver, or the reflector and the receiver to reduce the concentration of solar radiation onto the receiver.

22. The method of claim 21, comprising the power supply powering the tracker with stored electric power.

23. The method of claim 21, comprising the power supply powering the tracker with direct current electric power generated by the solar energy collector.

24. A method of operating the solar energy collector system of claim 18, comprising:
detecting a fault on the external load;
ceasing to provide alternating current from the inverter to the external load;
continuing to power the pump to circulate heat transfer fluid through the receiver; and
powering the tracker from the power supply to orient the reflector, the receiver, or the reflector and the receiver to continue concentrating solar radiation onto the receiver.

25. The method of claim 24, comprising the power supply powering the tracker and the pump with stored electric power.

26. The method of claim 24, comprising the power supply powering the tracker and the pump with direct current electric power generated by the solar energy collector.

27. The solar energy collector system of claim 14, comprising:
a second solar energy collector located proximate to the first solar energy collector and including:
a solar energy receiver;
a reflector; and
a tracker configured to orient the reflector, the receiver, or the reflector and the receiver to track motion of the sun in the sky so that solar radiation is concentrated by the reflector onto the receiver;
wherein the receiver includes one or more solar cells that, in operation of the solar energy collector, are illuminated by solar radiation concentrated by the reflector onto the receiver, and the receiver also includes one or more fluid channels through which, in operation of the solar energy collector, heat transfer fluid may pass to collect heat from solar radiation concentrated by the reflector onto the receiver; and
a second integrated balance of system located proximate to the second solar energy collector and including:
an inverter electrically coupled to the receiver in the second solar energy collector to receive direct current from the second solar energy collector and configured to convert the direct current to alternating current,
a heat transfer fluid control system including a controller, a pump controlled by the controller, and a power supply electrically coupled to the inverter to receive alternating current electric power from the inverter, the power supply providing electric power to the controller and to the pump, the heat transfer fluid control system configured to circulate a heat transfer fluid through the second solar energy collector;
an alternating current electric power output electrically coupled to the inverter to provide alternating current from the inverter to an external load the same as or different from the external load to which the first integrated balance of system is coupled;
a first heat transfer fluid inlet configured to receive heat transfer fluid from an external supply the same as or different from the external supply to which the first integrated balance of system is coupled;
a first heat transfer fluid outlet coupled to the receiver in the second solar energy collector to provide heat transfer fluid received from the external supply to the second solar energy collector;
a second heat transfer fluid inlet coupled to the receiver in the second solar energy collector to receive heat transfer fluid from the second solar energy collector; and
a second heat transfer fluid outlet configured to provide heat transfer fluid received from the second solar energy collector to the same external use or external user as that of the first integrated balance of system;
wherein the first integrated balance of system controls the direct current electric output of the first solar energy collector at a first current-voltage power point and controls the temperature and flow rate of heat transfer fluid through the first solar energy collector at a first output temperature and a first flow rate;
the second integrated balance of system controls the direct current electric output of the second solar energy collector at a second current-voltage power point and controls the temperature and flow rate of heat transfer fluid through the second solar energy collector at a second output temperature and a second flow rate; and
the first current voltage power point, first output temperature, and first flow rate are controlled independently of the second current-voltage power point, second output temperature, and second flow rate.

28. A heat and electricity providing system comprising:
at least a first solar energy collector including:
a solar energy receiver;
a reflector; and
a tracker configured to orient the reflector, the receiver, or the reflector and the receiver to track motion of the sun in the sky so that solar radiation is concentrated by the reflector onto the receiver; wherein:
the receiver includes one or more solar cells that, in operation of the solar energy collector, are illuminated by solar radiation concentrated by the reflector onto the receiver, and the receiver also includes one or more fluid channels through which, in operation of the solar energy collector, a heat transfer fluid may pass to collect heat from solar radiation concentrated by the reflector onto the receiver; and
the solar energy collector is fluidly coupled to an external source of the heat transfer fluid to be heated in the receiver, fluidly coupled to an external use or external user of the heat transfer fluid that has been heated in the receiver, and electrically coupled to deliver electric power generated by the receiver to an external load; and
an electrically powered heat pump fluidly coupled to a source of heat transfer fluid to be heated by the heat pump and fluidly coupled to the same external use or external user of heated heat transfer fluid as is the solar energy collector.

29. The heat and electricity providing system of claim 28, wherein the heat pump is fluidly coupled to the same external source of heat transfer fluid as is the solar energy collector.

30. The heat and electricity providing system of claim 28, wherein the heat pump is electrically coupled to the solar energy collector to be powered by electric power generated by the solar energy collector.

31. The heat and electricity providing system of claim 28, configured so that a total heat requirement of the external use or external user of heat transfer fluid during a predetermined time period is satisfied by a combination of:
a total heat output delivered from the solar energy collector to the external use or external user during the predetermined time period; and
a total heat output delivered from the heat pump to the external use or external user during the predetermined time period, wherein the heat pump is powered during the predetermined time period by a total electric energy less than or equal to the total electric energy generated by the solar energy collector during the predetermined time period.

32. The heat and electricity providing system of claim 31, wherein the total heat output delivered from the solar energy collector to the external use or external user during the predetermined time period is equal to about one half of the total heat requirement of the external use or external user of heat during the predetermined time.

33. The heat and electricity providing system of claim 31, wherein the predetermined time period is about one year.

34. The heat and electricity providing system of claim 28, comprising at least a first integrated balance of system located proximate to the first solar energy collector and including:
an inverter electrically coupled to the receiver to receive direct current from the solar energy collector and configured to convert the direct current to alternating current;
a heat transfer fluid control system including a controller, a pump controlled by the controller, and a power supply electrically coupled to the inverter to receive alternating current electric power from the inverter, the power supply providing electric power to the controller and to the pump, the heat transfer fluid control system configured to circulate a heat transfer fluid through the solar energy collector;
an alternating current electric power output electrically coupled to the inverter to provide alternating current from the inverter to an external load;
a first heat transfer fluid inlet configured to receive heat transfer fluid from an external supply;
a first heat transfer fluid outlet coupled to the receiver to provide heat transfer fluid received from the external supply to the solar energy collector;
a second heat transfer fluid inlet coupled to the receiver to receive heat transfer fluid from the solar energy collector; and
a second heat transfer fluid outlet configured to provide heat transfer fluid received from the solar energy collector to an external use or external user.

35. The heat and electricity providing system of claim 34, wherein the controller controls operation of the heat pump.

36. A method of operating the heat and electricity providing system of claim 28 comprising controlling the operation of the heat pump based on an expected demand for heat and an expected availability of heat and electric power from the solar energy collector.

37. A method of operating the heat and electricity providing system of claim 28 comprising controlling the operation of the heat pump based on an expected demand for heat and on a record of prior heat and electric power output from the solar energy collector.
